(19) United States
(12) Patent Application Publication
(10) Pub. No.: US 2010/0321360 A1
(43) Pub. Date: Dec. 23, 2010

(54) Differential signal receiving circuit and display apparatus

(75) Inventor: Toshikazu Murata, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Renesas Electronics Corporation, Kawasaki (JP)

(21) Appl. No.: 12/801,255

(22) Filed: May 28, 2010

(30) Foreign Application Priority Data
Jun. 22, 2009 (JP) 2009-147366

(51) Int. Cl. G09G 5/00; H03F 3/45; H03K 3/00

(52) U.S. Cl. 345/209; 327/53; 327/108

(57) ABSTRACT

A differential signal receiving circuit includes: a first differential circuit of a plurality of depletion type transistors of a first conductive type and having a first output node and a second output node; and a second differential circuit of a plurality of enhancement type transistors of a second conductive type opposite to the first conductive type, and having output nodes respectively connected with the first and second output nodes. An inverter circuit is connected between the first output node and the second output node.

### INCORPORATION BY REFERENCE

This patent application claims a priority on convention based on Japanese Patent Application No. 2009-147366 filed on Jun. 22, 2009. The disclosure thereof is incorporated herein by reference.

### TECHNICAL FIELD

The present invention relates to a differential signal receiving circuit for receiving a small amplitude differential signal and to a display apparatus having the differential signal receiving circuit.

### BACKGROUND ART

In these years, a thin and low-power flat panel display apparatus is mainly used as a monitor of a personal computer (PC) and a television receiver. In a liquid crystal display apparatus that is representative in the flat panel display apparatus, a technique is rapidly developed to significantly increase the numbers of display pixels and simultaneously displayed colors. In the liquid display apparatus, a digital data signal representing display data is inputted externally, converted into an analog voltage signal, and applied to liquid crystal pixels to display an image on a screen. In transmission of the digital data signal representing the display data, a data transmission standard is applied which uses the small amplitude differential signal such as the RSDS (Reduced Swing Differential Signaling) and the miniLVDS (mini-Low Voltage Differential Signaling). Since a data amount increases as the numbers of display pixels and simultaneously generated colors increase, it is desired in the display apparatus that the transmission of the display data becomes faster. Accordingly, a display driver requires a receiving circuit for converting the inputted small amplitude differential signal into an internal logic voltage signal at a high speed.

In the signal representing the display data, the voltage and amplitude fluctuate due to manufacturing variations, reflections, noises, and the like in a transmission system. For this reason, in a signal outputted from the receiving circuit, a delay time fluctuates and a duty ratio showing a ratio between a period in a high (H) level and a period in a low (L) level in a waveform fluctuates. The techniques for reducing the fluctuations disclosed in a patent literature 1 and a patent literature 2 are known.

FIG. 1 shows a block diagram showing a configuration of a circuit disclosed in the patent literature 1. The circuit includes a differential pair 10 of P-channel MOS transistors, a differential pair 20 of N-channel MOS transistors, a P-channel MOS transistor 31, an N-channel MOS transistor 34, switches 32, 33, 35, and 36, inverters 37 and 46, and a current summation circuit 40.

A differential signal VIN+ and VIN− is supplied to each of the differential pair 10 and the differential pair 20. The P-channel MOS transistor 31 is connected between the differential pair 10 and a power supply voltage VDD and serves as a current source. A gate of the P-channel MOS transistor 31 is connected to a bias voltage VBSP via the switch 32 and connected to the power supply voltage VDD via the switch 33. The N-channel MOS transistor 34 is connected between the differential pair 20 and a power supply voltage VSS and serves as a current source. A gate of the N-channel MOS transistor 34 is connected to a bias voltage VBSN via the switch 35 and connected to a power supply voltage VSS via the switch 36. The outputs of the differential pairs 10 and 20 are added by the current summation circuit 40, and the addition resultant signal is outputted from an output terminal OUT via the inverter 46.

The open and close of the switches 32 and 35 are controlled on the basis of a control signal Sc. In addition, the switches 33 and 36 are controlled on the basis of a signal having a logic level opposite to that of the control signal Sc due to the inverter 37. Accordingly, the above-mentioned two differential pairs 10 and 20 are controlled by the inverter 37 on the basis of the control signal Sc so that any one of the differential pairs can operate.

An operation one of the differential pairs is switched depending on a voltage range of the differential signal. That is, as shown in FIG. 2, when a voltage Vcm that is a center value of the voltage range of the differential signal is a voltage VDD/2 or more, the differential pair 20 of N-channel MOS transistors is controlled to be activated, and when being the voltage VDD/2 or less, the differential pair 10 of P-channel MOS transistors is controlled to be activated.

When the voltage Vcm is the voltage VDD/2 or more, to activate the differential pair 20, the switch 35 is closed and the switch 36 is opened. The bias voltage VBSN is applied to the gate of the transistor 34, and the transistor 34 operates as a constant current source to activate the differential pair 20. At this time, the switch 32 is opened and the switch 33 is closed. Accordingly, the voltage VDD is applied to the gate of the transistor 34, so that the transistor 31 will be in an off-state to inactivate the differential pair 10.

When the voltage Vcm is the voltage VDD/2 or less, to activate the differential pair 10, the switch 32 is closed and the switch 33 is opened. The bias voltage VBSP is applied to the gate of the transistor 31, and the transistor 31 operates as a constant current source to activate the differential pair 10. At this time, the switch 35 is opened and the switch 36 is closed. Accordingly, the voltage VSS is applied to the gate of the transistor 34, so that the transistor 34 will be in the off-state to inactivate the differential pair 20.

As described above, by activating any one of the differential pair 10 and the differential pair 20 depending on the voltage Vcm of the differential signal, the voltage range of the receivable differential signal can be extended. However, to realize the extension, it is required to switch the control signal Sc outside the receiving circuit. In addition, when the voltage range of the differential signal is in the vicinity of the voltage Vcm, it is hard to determine the differential pair to be activated. Moreover, the switched differential pair sometimes has a different characteristic, so that a delay time and a duty ratio may be degraded.

Next, referring to a block diagram shown in FIG. 3, a circuit disclosed in the patent literature 2 will be described. A node NVI+ and a node NVI− are input nodes to which a differential signal is inputted. Transistors 51 and 52 constitute a differential circuit, and their sources are commonly connected to a constant current source 61 for outputting a constant current I1. A drain of the transistor 52 is connected to a constant current source 63 for outputting a constant current I3 and to a gate of the transistor 54 via a current mirror circuit 72. A drain of the transistor 51 is connected to a constant current source 62 l for outputting a constant current I2 and to a gate of the transistor 53 via a current mirror circuit 71. A drain of the transistor 53 is connected to the node A and directly serves as an output node NVO1. A drain of the transistor 54 is connected to the node B and directly serves as an output node NVO2. Inverters 81 and 82 are connected between the node A and the node B in a cross-coupling manner.

Representing a voltage of the input node NV1+ as VIN+ and a voltage of the input node NV1− as VIN−, when (VIN+)>(VIN−), that is, a voltage difference exists between the input nodes, the transistor 52 is turned on and the transistor 51 is turned off. Accordingly, the current I1 flows to the transistor 52.

In this case, when the current values of the constant current sources 61 and 63 are in a relation of I1>I3, a gate voltage of the transistor 54 rises to turn on the transistor 54. Accordingly, the voltage at the node B is in the power supply voltage VSS (GND: an L level). Since the transistor 53 is turned off, the voltage at the node A is in the power supply voltage VDD (an H level). In this manner, the node NA and the node NB are in a reversed phase relation. Accordingly, a latch circuit including the inverters 81 and 82 operates, and the output node NVO1 is in the H level and the output node NVO2 is in the L level.

As described above, when the output nodes NVO1 and NVO2 output the reversed phase voltages, the latch circuit including the inverters 81 and 82 operates, to accelerate the switching of the output voltages. In this manner, it is prevented that the duty ratio representing a ratio between a period of the H level and a period of the L level in an output waveform becomes unstable.

However, in the above-mentioned circuit, when a voltage difference of the differential signal is small, the latch circuit does not operate well so that the output becomes unstable. FIG. 4 is a diagram showing a relationship between currents I51 and I52 flowing through the differential transistors 51 and 52; and current values I1, I2, and I3 of the constant current sources 61, 62, and 63. Here, it is supposed that I2=I3=I1/2, and an input differential signal is given as shown at the timing t1 in FIG. 2. As shown in FIG. 4, in a case of Vdiff=(VIN+)−(VIN−)=0.4 V, the current I52 flowing through the transistor 52 becomes substantially equal to the current I1 flowing in the current source 61, and the current I51 flowing through the transistor 51 becomes almost zero. Accordingly, the transistor 54 is turned on and the transistor 53 is turned off. In this case, since a voltage Vout2 at the output node NVO2 is in the L level, the latch circuit including the inverters 81 and 82 operate and thus the voltage Vout1 at the output node NVO1 is in the H level.

Since the transistor 54 operates depending on the gate voltage, a change rate of the gate voltage is correlated to a current difference (I52−I3) between the current I52 flowing through the transistor 52 and the current I3 flowing through the constant current source 63. As the current difference (I52−I3) becomes larger, the operation speed can be made faster. Meanwhile, in a case of Vdiff=(VIN+)−(VIN−)=0.2 V, the current difference (I52−I3) becomes small in comparison with the case of Vdiff=0.4V. Accordingly, the change rate of the gate voltage becomes slow. Thus, when a circuit operation frequency increases, data is switched to the next data before the voltages at the output nodes NVO1 and NVO2 are completely switched. For this reason, the voltages VOUT1 and VOUT2 change in the vicinity of threshold voltages of the inverters 81 and 82. Therefore, the latch circuit including the inverters 81 and 82 does not operate, and the output becomes unstable.

In addition, since the differential circuit in the signal input stage includes the N-channel MOS transistors, the receiving circuit cannot operate in a case of a low input voltage. Regarding this case, the explanation will be made referring to FIG. 5. In FIG. 5, the constant current source 61 is replaced by a transistor 50. Representing voltages between the gates and sources of the transistors 51 and 52 as Vgs1 and Vgs2, respectively, the constant current source 50 outputs a constant current I1 in response to a bias voltage BIASN applied to the gate of the transistor 50. A lower limit of the input voltage is as follows. Supposing that the input voltage difference Vdiff=(VIN+)−(VIN−) is 0.4 V, a saturation voltage Vds(sat) of the transistor 50 is 0.2 V, a voltage Vgs2 between the gate and source when the current I1 flows through the transistor 52 is 1 V, Vgs2+Vds(sat)=1+0.2=1.2 V. That is, since the transistor 50 is satisfied even when a signal of 1.2 V or less is inputted, the circuit cannot operate.

As described above, since the input voltage range changes in the transmission system due to reflections, noises, manufacturing variations, and the like, the conventional differential signal receiving circuit requires that an input data voltage range and an input data differential amplitude range are wide.

### CITATION LIST

[Patent literature 1]: JP 2004-297462A

[Patent literature 2]: JP-A-Heisei 5-67950

### SUMMARY OF THE INVENTION

In an aspect of the present invention, a differential signal receiving circuit includes: a first differential circuit comprising a plurality of depletion type transistors of a first conductive type and having a first output node and a second output node; a second differential circuit comprising a plurality of enhancement type transistors of a second conductive type opposite to the first conductive type, and having output nodes respectively connected with the first and second output nodes; and an inverter circuit connected between the first output node and the second output node.

In another aspect of the present invention, a display apparatus includes: a display panel comprising data lines, scan lines, and pixels arranged at intersections of the data lines and the scan lines; a gate driver circuit configured to sequentially drive the scan lines in response to a control signal; and a source driver circuit configured to drives the data lines in response to a data signal. The source driver circuit comprises a differential signal receiving circuit receives the data signal. The differential signal receiving circuit includes: a first differential circuit comprising a plurality of depletion type transistors of a first conductive type and having a first output node (NA) and a second output node; a second differential circuit comprising a plurality of enhancement type transistors of a second conductive type opposite to the first conductive type, and having output nodes respectively connected with the first and second output nodes (NA, NB); and an inverter circuit connected between the first output node and the second output node.

In still another aspect of the present invention, a differential signal receiving method is achieved by receiving a differential signal by a differential pair of depletion type transistors of a first conductive type; by receiving the differential signal by a differential pair of enhancement type transistors of a second conductive type opposite to the first conductive type; by supplying currents corresponding to currents which flows through the depletion type transistors, from current mirror circuits connected with the depletion type transistors to first and second nodes, respectively; by supplying currents corresponding to currents which flows through the enhancement type transistors, from current mirror circuits connected with the enhancement type transistors to the first and second nodes, respectively; and by driving the second node based on a voltage of the first node by an inverter whose input is connected to the first node and whose output is connected to the second node.

According to the present invention, a differential signal receiving circuit can output a stable signal with low jitter even in a case of small differential input amplitude.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a diagram showing a configuration of a conventional differential circuit;

FIG. 2 is a waveform diagram showing a differential signal inputted to the conventional differential circuit;

FIG. 3 is a diagram showing a configuration of another conventional differential circuit;

FIG. 4 is a diagram showing a relation between a voltage and a current applied to a transistor of a differential stage;

FIG. 5 is a diagram showing an input voltage range;

FIG. 6 is a diagram showing a configuration of a liquid crystal display apparatus according to an embodiment of the present invention;

FIG. 7 is a diagram showing a configuration of a source driver circuit according to the embodiment of the present invention;

FIG. 8 is a diagram showing a configuration of a differential signal receiving circuit according to the embodiment of the present invention;

FIG. 9 is a diagram showing an input signal and an operation range;

FIG. 10 is a diagram showing the input voltage range (N channel);

FIG. 11 is a diagram showing the input voltage range (P channel);

FIG. 12 is a diagram showing a simulation result of an operation of a circuit to be compared;

FIG. 13 is a diagram showing a simulation result of an operation of the receiving circuit of the present invention; and

FIG. 14 is a diagram showing a configuration of the receiving circuit according to another embodiment of the present invention.

### DESCRIPTION OF EMBODIMENTS

Hereinafter, a display apparatus using a differential signal receiving circuit of the present invention will be described with reference to the attached drawings.

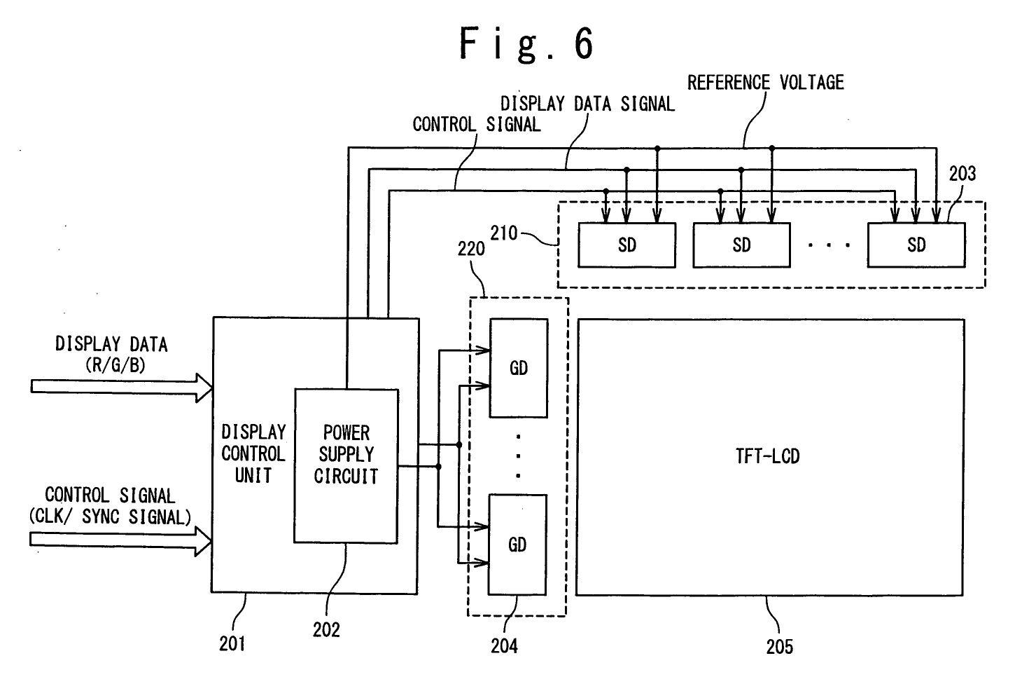

FIG. 6 is a block diagram of a liquid crystal display apparatus according to the present invention. The liquid crystal display apparatus includes a display control unit 201, a power supply circuit 202 housed in the display control unit 201, a source driver circuit of source drivers (SD) 203, a gate driver circuit of gate drivers (GD) 204, and a liquid crystal panel (TFT-LCD: Thin Film Transistor-Liquid Crystal Display) panel 205. In the liquid crystal panel 205, pixels are arranged in a matrix at intersection points of data lines and scan lines. The display control unit 201 supplies a display data signal and a control signal to the source driver circuit 210 and the gate driver circuit 220. The power supply circuit 202 supplies a reference voltage required for operation of the source drivers 203 and the gate drivers 204.

The source driver circuit 210 drives the data lines along a column direction of the liquid crystal panel 205 on the basis of the display data signal and the control signal. The gate driver circuit 220 drives the scan lines along a row direction of the liquid crystal panel 205 on the basis of the control signal.

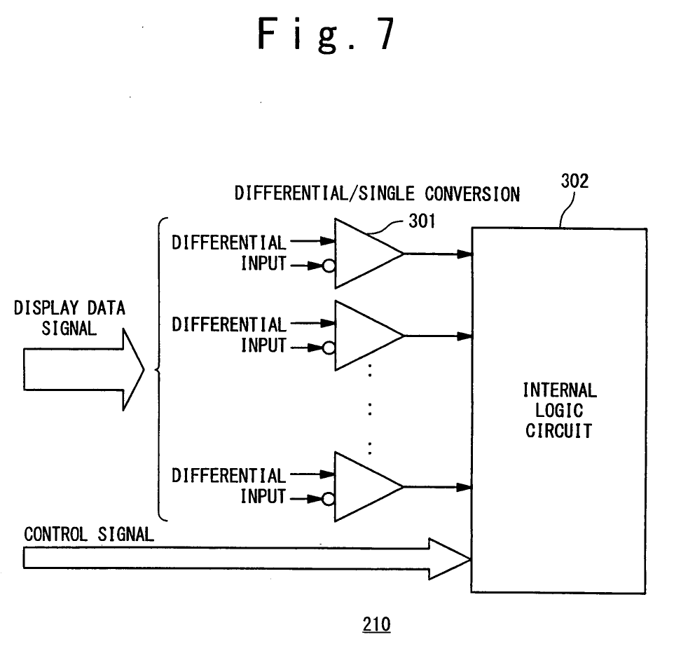

Here, FIG. 7 shows an internal block diagram of the source driver circuit 210 for receiving the display data signal. The display data signal is a signal representing color data, which is transmitted as a differential signal with small amplitude. The source driver circuit 210 receives the display data signal by receiving circuits 301. Each of the receiving circuits 301 converts the differential signal into a single end signal and outputs the signal to an internal logic circuit 302. The single end signal is subjected to the serial-parallel conversion in the internal logic circuit 302 in response to the control signal, is subjected a D/A (Digital/Analog) conversion, and finally is outputted to the liquid crystal panel 205.

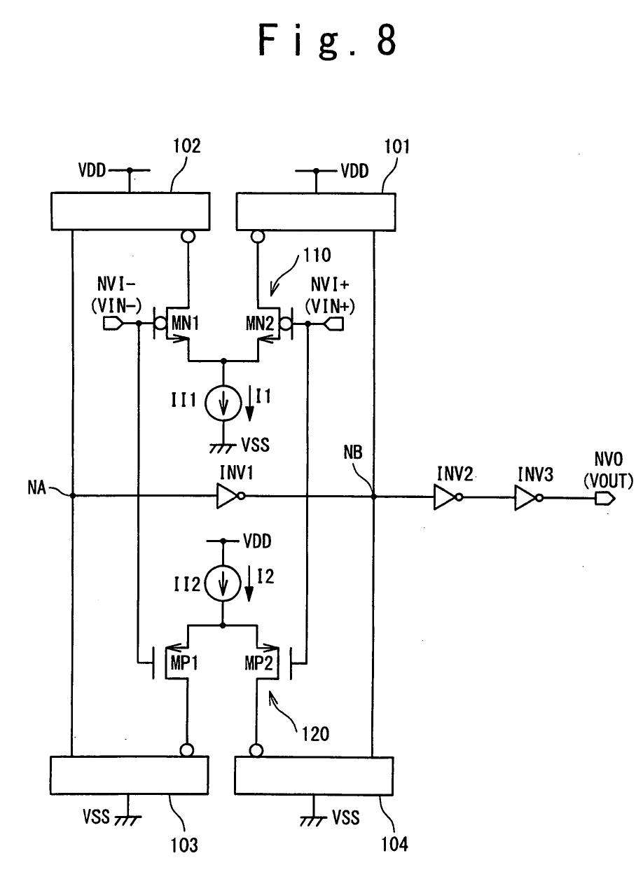

FIG. 8 is a circuit diagram of a differential signal receiving circuit used in the receiving circuit 301. The differential signal receiving circuit includes a differential circuit 110 of N-channel MOS transistors MN1 and MN2, a differential circuit 120 of P-channel MOS transistors MP1 and MP2, constant current sources II1 and II2, current mirror circuits 101 to 104, and inverters INV1 to INV3.

The transistors MN1 and MN2 are depletion type transistors, which configure the differential circuit 110. Accordingly, sources of the transistors MN1 and MN2 are commonly connected to the power supply voltage VSS via the constant current source II1 outputting the constant current I1. A drain of the transistor MN1 is connected to a reference current node of the current mirror circuit 102. A drain of the transistor MN2 is connected to a reference current node of the current mirror circuit 101. The transistors MP1 and MP2 configure a differential circuit 120, and sources thereof are commonly connected to the power supply voltage VDD via the constant current source II2 outputting the constant current I2. A drain of the transistor MP1 is connected to a reference current node of the current mirror circuit 103. A drain of the transistor MP2 is connected to a reference current node of the current mirror circuit 104. Gates of the transistors MN1 and MP1 are both connected to an input node NVI−. Gates of the transistors MN2 and MP2 are both connected to an input node NVI+. A differential signal is inputted to the input nodes NVI+ and NVI−. A voltage of the input node NVI+ is shown as VIN+, and a voltage of the input node NVI− is shown as VIN−.

An output node of the current mirror circuit 102 and an output node of the current mirror circuit 103 are connected to a node NA. An output node of the current mirror circuit 101 and an output node of the current mirror circuit 104 are connected to a node NB. The node NA is connected to an input of the inverter INV1, and the node NB is connected an output of the inverter INV1. Inverters INV2 and INV3 are connected in series between the node NB and the output node NVO of the receiving circuit.

The current mirror circuits 101 and 102 are connected to the power supply voltage VDD to supply currents from the output node to the nodes NA and NB on the basis of a current flowing to a reference current node. The current mirror circuits 103 and 104 are connected to the power supply voltage VSS to supply currents from the nodes NA and NB to the output node on the basis of the current flowing the reference current node.

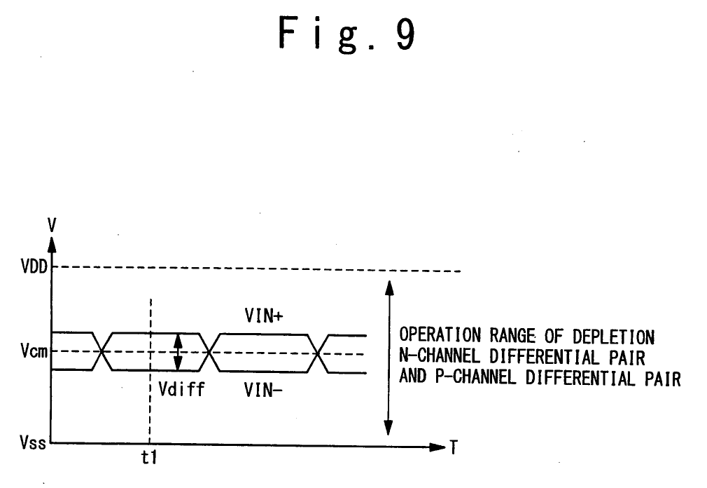

An operation at timing t1 shown in FIG. 9 will be described. Specifically, a differential signal is supplied to the input nodes NVI+ and NVI− with a relation of (VIN+)>(VIN−).

Since the relation of (VIN+)>(VIN−) is satisfied, the transistor MN2 is turned on, and the transistor MN1 is turned off. Accordingly, the constant current I1 flows through the transistor MN2 in the differential circuit 110 of the depletion type transistors MN1 and MN2. In this case, the current mirror circuit 101 operates, and the current mirror circuit 102 stops. Similarly, the transistor MP1 is turned on, and the transistor MP2 is turned off. Accordingly, the constant current I2 flows through the transistor MP1 in the differential circuit 100 of the transistors MP1 and MP2. In this case, the current mirror circuit 103 operates, and the current mirror circuit 104 stops.

Since the current mirror circuit 101 operates and the current mirror circuit 104 stops, a voltage of the node NB rises. Similarly, since the current mirror circuit 103 operates and the current mirror circuit 102 stops, a voltage of the node NA falls. Since the voltage of the node NA falls, an output voltage of the inverter INV1 becomes high, which raises the voltage of the node NB. In such an operation, the differential signal is converted into the single end signal in the node NB, and is outputted to the output node NVO as the single end signal VOUT using the inverters INV2 and INV3 as buffers.

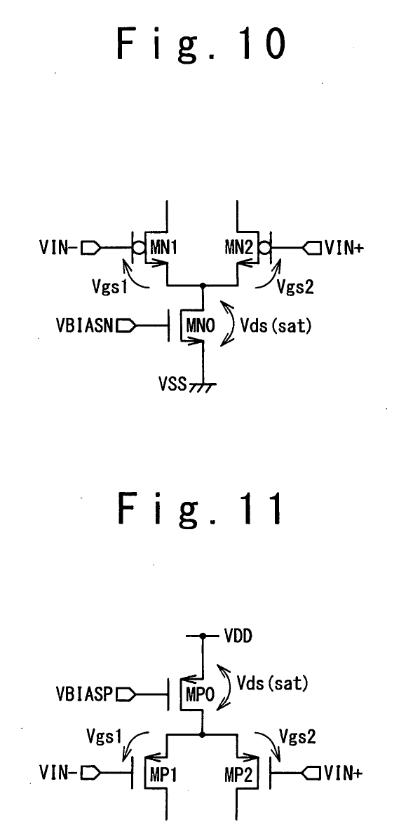

Here, referring to FIG. 10, a lower limit of the input voltage range will be described. Voltages between the gate and the source of the transistors MN1 and MN2 are supposed to be Vgs1 and Vgs2, respectively. In the constant current source II1, the bias voltage VBIASN is applied to a transistor MN0 to output the current I1. In a case of the timing t1 shown in FIG. 9, assuming that a saturated voltage Vds(sat) of the transistor MN0 is 0.2V and that the voltage Vgs2 between the gate and source when the current I1 flows through the transistor is 0 V since the transistor MN1 is the depletion type transistor, the lower limit of the input voltage is Vgs2+Vds(sat)=0+0.2=0.2 V. That is, a data signal having a signal level equal to or higher than 0.2 V can be inputted.

Referring to FIG. 11, an upper limit of the input voltage range will be described. Voltages between the gate and the source of the transistors MP1 and MP2 are assumed to be represented as Vgs1 and Vgs2, respectively. In the constant current source II2, the bias voltage VBIASP is applied to a transistor MP0. In the case of the timing t1 shown in FIG. 9, assuming that a saturated voltage Vds(sat) of the transistor MP0 is 0.2 V and assuming that the voltage Vgs1 between the gate and the source when the current I2 flows through the transistor MP1 is 1 V, the upper limit of the input voltage is Vgs1+Vds(sat)=1+0.2=1.2 V. That is, a data signal having a signal level equal to or lower than (VDD−1.2) V can be inputted.

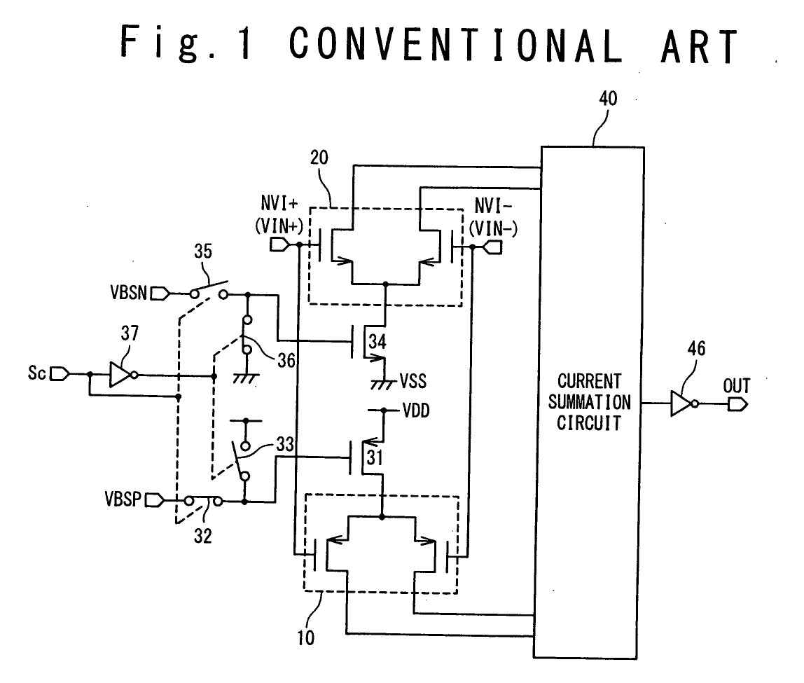

In the circuit shown in FIG. 1, in order to extend the input voltage range, it is required to switch the control signal Sc supplied from outside through a control terminal in accordance with the input voltage. In the present invention, since the input voltage range is wide, the control terminal for an external signal is not required. That is, there is no need to switch the operating transistor by an external control circuit, and also the input voltage range can be extended to accept a small amplitude signal.

Next, an operation when a differential signal of a small voltage difference (Vdiff) is inputted between the input nodes NVI+ and NVI− will be described.

Firstly, in the circuit shown in FIG. 8, an operation when there is not the inverter INV1 will be described. When the input differential signal is inputted to the input nodes NVIN+ and NVI− with the relation of (VIN+)>(VIN−), the transistor MN2 is turned on, and the transistor MN1 is turned off. Accordingly, the constant current I1 flows through the transistor MN2 in the differential circuit having the depletion type transistors MN1 and MN2. In this case, the current mirror circuit 101 operates, and the current mirror circuit 102 stops. Meanwhile, the transistor MP1 is turned on, and the transistor MP2 is turned off. Accordingly, the constant current I2 flows through the transistor MP1 in the differential circuit having the transistors MP1 and MP2. In this case, the current mirror circuit 103 operates, and the current mirror circuit 104 stops.

Since the current mirror circuit 101 operates and the current mirror circuit 104 stops, the voltage of the node NB rises. In addition, since the current mirror circuit 103 operates and the current mirror circuit 102 stops, the voltage of the node NA falls. FIG. 12 shows waveforms at the time of simulating the state. When the voltage difference (Vdiff) of the input differential signal is small and an operation frequency is high, the voltage waveforms of the nodes NA and NB will be waveforms similar to the sine curve.

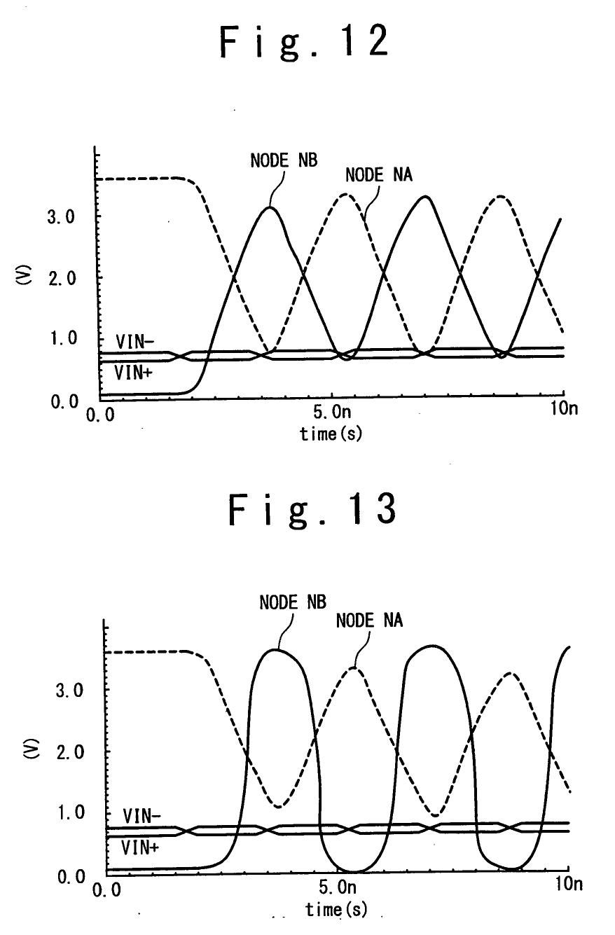

Next, as shown in FIG. 8, an operation when there is the inverter INV1 will be described. In the nodes NA and NB, the voltages are in a reversed phase relation. For example, when the node NA changes into the L level, the inverter INV1 operates so that the node NB is in the H level. That is, the inverter INV1 supplied with a signal level at the node NA operates to assist the voltage change of the node NB. Accordingly, as shown in FIG. 13, the inverter INV1 enlarges a voltage amplitude at the node NB. Thus, even when the voltage difference (Vdiff) of the input difference signal is small, an output with large amplitude can be obtained. In addition, since transition times in the rising and rising of a waveform are shortened by the inverter INV1, a signal with a stable duty ratio and with low jitter is outputted to the output node NVO.

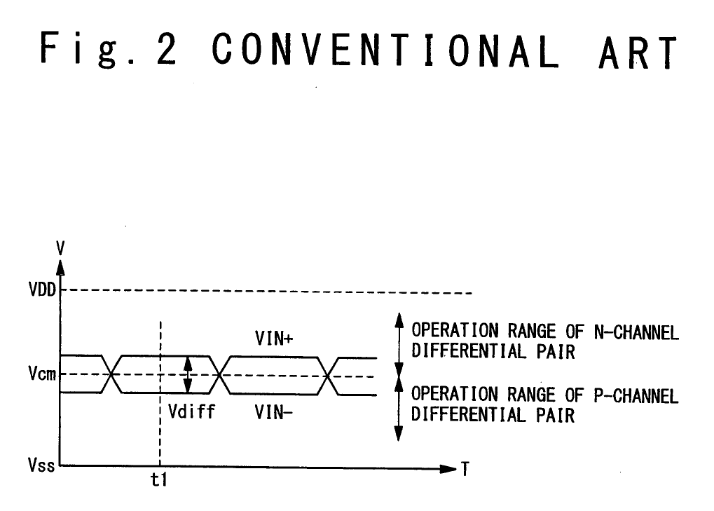

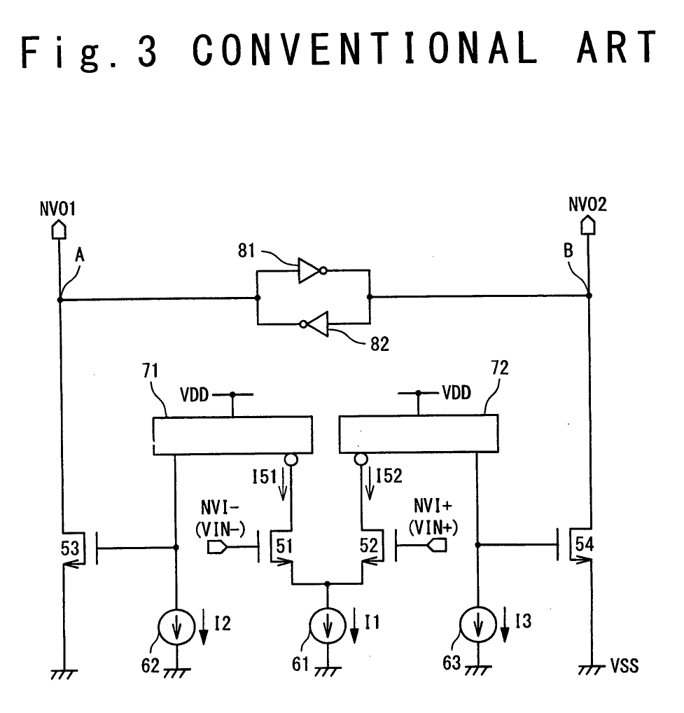

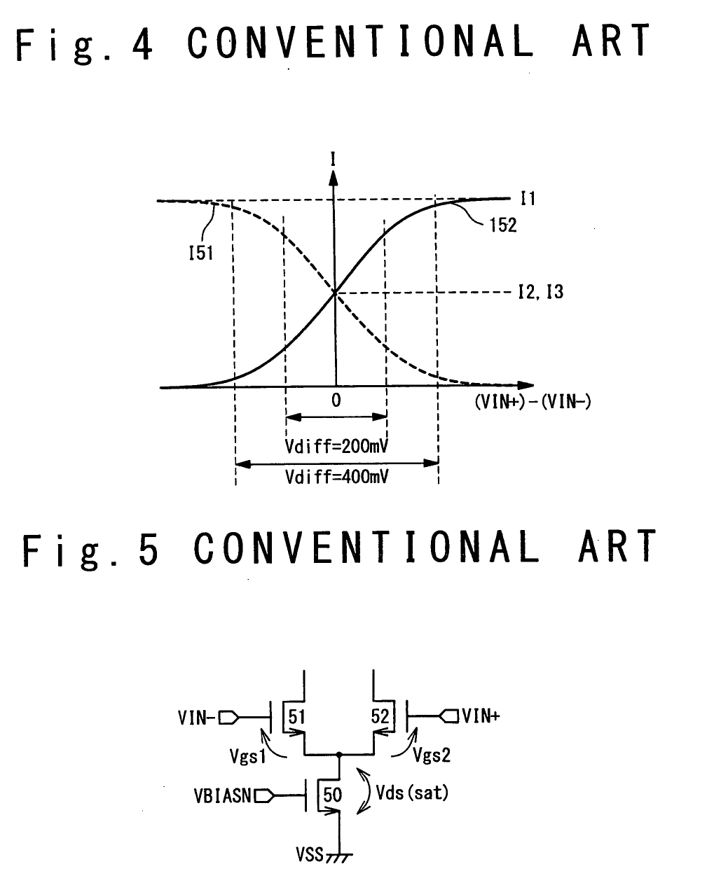

In the circuit shown in FIG. 2, when the voltage difference (Vdiff) of the input difference signal is small, a latch circuit does not operate and the output becomes unstable. However, in the present invention, as described above, the stable operation can be realized even when the input voltage difference (Vdiff) is small.

As described above, when the differential amplifier circuit of the depletion type N-channel MOS transistors that are non-doped transistors is combined with the differential amplifier circuit of the enhancement type P-channel MOS transistors, the input voltage range can be extended. Moreover, when the inverter is provided between the differential signals whose phases are opposite to each other and an assist operation is carried out by the inverter, the voltage switching can be carried out in a short time, and accordingly the differential signal receiving circuit can operate stably even when the input voltage difference (Vdiff) is small.

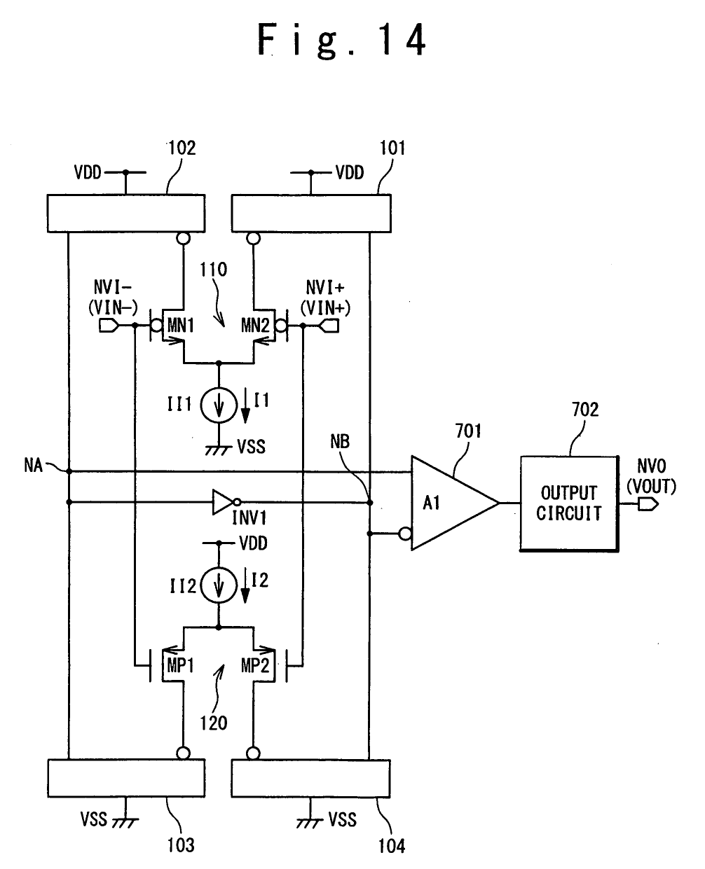

FIG. 14 is a diagram showing an example of connection of a differential amplifier 701 that has a gain A1, instead of the inverter INV2 used as a comparator and that is connected with the nodes NA and NB. An output of the differential amplifier 701 is connected to the output node NVO via an output circuit 702. In this manner, the output can obtain a stable duty even when the input voltage difference (Vdiff) is small.

As described above, according to the present invention, when the differential stage of the depletion type N-channel MOS transistors is combined with the differential stage of the enhancement type P-channel MOS transistors, the voltage range of the input signal can be enlarged. Moreover, even when the voltage difference of the input difference signal is small, a signal with stable duty ratio can be outputted.

When the input signal is a small amplitude signal near the power supply voltage VDD, it is preferred to combine the differential stage of the depletion type P-channel MOS transistors with the differential stage of the enhancement type N-channel MOS transistors.

What is claimed is:

1. A differential signal receiving circuit comprising:
a first differential circuit comprising a plurality of depletion type transistors of a first conductive type and having a first output node and a second output node;
a second differential circuit comprising a plurality of enhancement type transistors of a second conductive type opposite to the first conductive type, and having output nodes respectively connected with said first and second output nodes; and
an inverter circuit connected between said first output node and said second output node.

2. The differential signal receiving circuit according to claim 1, further comprising:
a waveform shaping circuit connected with said second output node and configured to output a single end signal,
wherein said inverter circuit has an input connected with said first output node and an output connected with said second output node.

3. The differential signal receiving circuit according to claim 1, further comprising:
a differential amplifier circuit having differential inputs connected with said first and second output nodes.

4. The differential signal receiving circuit according to claim 1, wherein said first differential circuit comprises:
a first constant current source connected in common to sources of said depletion type transistors and configured to supply a constant current to said depletion type transistors;
a first current mirror circuit connected with a drain of one of said depletion type transistors and configured to supply a current corresponding to a current flowing through said one depletion type transistor to said first output node; and
a second current mirror circuit connected with a drain of the other of said depletion type transistors and configured to supply a current corresponding to a current flowing through said other depletion type transistor to said second output node, and
wherein said second differential circuit comprises:
a second constant current source connected in common to sources of said enhanced type transistors and configured to supply a constant current to said enhanced type transistors;
a third current mirror circuit connected with a drain of one of said enhanced type transistors and configured to supply a current corresponding to a current flowing through said one enhanced type transistor to said first output node; and
a fourth current mirror circuit connected with a drain of the other of said enhanced type transistors and configured to supply a current corresponding to a current flowing through said other enhanced type transistor to said second output node.

5. The differential signal receiving circuit according to claim 1, wherein said first differential circuit comprises a differential pair of depletion type N-channel MOS transistors, and
wherein said second differential circuit comprises a differential pair of enhancement type P-channel MOS transistors.

6. A display apparatus comprising:
a display panel comprising data lines, scan lines, and pixels arranged at intersections of said data lines and said scan lines;
a gate driver circuit configured to sequentially drive said scan lines in response to a control signal; and
a source driver circuit configured to drives said data lines in response to a data signal,
wherein said source driver circuit comprises a differential signal receiving circuit receives said data signal,
wherein said differential signal receiving circuit comprises:
a first differential circuit comprising a plurality of depletion type transistors of a first conductive type and having a first output node and a second output node;
a second differential circuit comprising a plurality of enhancement type transistors of a second conductive type opposite to the first conductive type, and having output nodes respectively connected with said first and second output nodes; and
an inverter circuit connected between said first output node and said second output node.

7. The display apparatus according to claim 6, further comprising:
a waveform shaping circuit connected with said second output node and configured to output a single end signal,
wherein said inverter circuit has an input connected with said first output node and an output connected with said second output node.

8. The display apparatus according to claim 6, further comprising:
a differential amplifier circuit having differential inputs connected with said first and second output nodes.

9. The display apparatus according to claim 6, wherein said first differential circuit comprises:
a first constant current source connected in common to sources of said depletion type transistors and configured to supply a constant current to said depletion type transistors;
a first current mirror circuit connected with a drain of one of said depletion type transistors and configured to supply a current corresponding to a current flowing through said one depletion type transistor to said first output node; and
a second current mirror circuit connected with a drain of the other of said depletion type transistors and configured to supply a current corresponding to a current flowing through said other depletion type transistor to said second output node, and
wherein said second differential circuit comprises:
a second constant current source connected in common to sources of said enhanced type transistors and configured to supply a constant current to said enhanced type transistors;
a third current mirror circuit connected with a drain of one of said enhanced type transistors and configured to supply a current corresponding to a current flowing through said one enhanced type transistor to said first output node; and
a fourth current mirror circuit connected with a drain of the other of said enhanced type transistors and configured to supply a current corresponding to a current flowing through said other enhanced type transistor to said second output node.

10. The display apparatus according to claim 6, wherein said first differential circuit comprises a differential pair of depletion type N-channel MOS transistors, and
wherein said second differential circuit comprises a differential pair of enhancement type P-channel MOS transistors.

11. The display apparatus according to claim 6, wherein said display panel comprises a liquid crystal display panel.

12. A differential signal receiving method comprising:
receiving a differential signal by a differential pair of depletion type transistors of a first conductive type;
receiving said differential signal by a differential pair of enhancement type transistors of a second conductive type opposite to the first conductive type;
supplying currents corresponding to currents which flows through said depletion type transistors, from current mirror circuits connected with said depletion type transistors to first and second nodes, respectively;
supplying currents corresponding to currents which flows through said enhancement type transistors, from current mirror circuits connected with said enhancement type transistors to said first and second nodes, respectively; and
driving said second node based on a voltage of said first node by an inverter whose input is connected to said first node and whose output is connected to said second node.
